(19) United States
(12) Patent Application Publication
(10) Pub. No.: US 2025/0377600 A1
(43) Pub. Date: Dec. 11, 2025

(54) ILLUMINATION ADJUSTMENT APPARATUSES AND LITHOGRAPHIC APPARATUSES

(71) Applicant: ASML Netherlands B.V., Veldhoven (NL)

(72) Inventors: Nicolae Marian UNGUREANU, Shelton, CT (US); James MELFI, Jr., Norwalk, CT (US); James F. CHESTER, New Milford, CT (US); Yuval KAMINER, Ridgefield, CT (US); Nicholas Stephen APONE, Fairfield, CT (US)

(73) Assignee: ASML Netherlands B.V., Veldhoven (NL)

(21) Appl. No.: 18/876,007

(22) PCT Filed: Aug. 18, 2023
(86) PCT No.: PCT/EP2023/072765

§ 371 Date: Dec. 17, 2024

Related U.S. Application Data
(60) Provisional application No. 63/406,992, filed on Sep. 15, 2022.

(51) Int. Cl. G03F 7/00

(52) U.S. Cl. CPC G03F 7/70141; G03F 7/70833; G03F 7/7085; G03F 7/70891; G03F 7/709; G03F 7/7095

(57) ABSTRACT

An illumination adjustment apparatus includes a plate, actuators, and finger structures. The actuators include coils disposed on the plate. The finger structures include beryllium alloy material. Ones of the finger structures are coupled to corresponding ones of the actuators via magnets. The finger structures are moved independently using the actuators, are disposed at least partially in a path of a beam of radiation to intercept at least a portion of the beam, and adjust an intensity cross-section of the beam based on the moving and the intercepting.

### CROSS-REFERENCE TO RELATED APPLICATIONS

This application claims priority of U.S. application 63/406,992 which was filed on 15 Sep. 2022, and which is incorporated herein in its entirety by reference.

### FIELD

The present disclosure relates to illumination systems, for example, illumination adjustment systems for adjusting cross-sectional intensities of illumination beams used in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which can be a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (photoresist or simply “resist”) provided on the substrate. In general, a single substrate will contain a network of adjacent target portions that are successively patterned. Known lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

Another lithographic system is an interferometric lithographic system where there is no patterning device, but rather a light beam is split into two beams, and the two beams are caused to interfere at a target portion of the substrate through the use of a reflection system. The interference causes lines to be formed at the target portion of the substrate.

A lithographic apparatus typically includes an illumination system that conditions radiation generated by a radiation source before the radiation is incident upon a patterning device. The illumination system may, for example, modify one or more properties of the radiation, such as polarization and/or illumination mode. The illumination system can include a uniformity correction system that corrects or reduces non-uniformities (e.g., intensity non-uniformities) present in the radiation. Uniformity correction devices can employ actuated fingers that are inserted into an edge of a radiation beam to correct intensity variations. A spatial breadth of illumination that can be adjusted by a uniformity correction system is dependent on, inter alia, sizes of the fingers and of the actuating devices used to move fingers in the uniformity correction system. Modifying finger sizes from a known working design is not trivial as such modifications can lead to undesirable alterations of one or more properties of a radiation beam, such as, e.g., a pupil formed by the radiation beam.

In order to achieve high quality pattern transfer to a substrate, it is desirable to control the cross-sectional intensity of a beam of radiation to correct for errors in radiation dosage. It is a problem that beams of radiation can have a non-conforming intensity profile. It is desirable for lithographic process to have a beam of radiation that is controllable such that improved uniformity can be achieved. A patterning device imparts a pattern onto a beam of radiation that is then projected onto a substrate. Image quality of this projected beam is affected by the uniformity of the beam.

### SUMMARY

Accordingly, it is desirable to control illumination uniformity so that lithographic tools perform lithography processes as accurately and as quickly as possible.

In some aspects, an illumination adjustment apparatus can comprise a plate, actuators, and finger structures. The actuators can comprise coils disposed on the plate. The finger structures can comprise beryllium alloy material. Ones of the finger structures can be coupled to corresponding ones of the actuators via magnets. The finger structures can be configured to be moved independently using the actuators, to be disposed at least partially in a path of a beam of radiation to intercept at least a portion of the beam, and to adjust an intensity cross-section of the beam based on the moving and the intercepting.

In some aspects, a lithographic apparatus can comprise an illumination system and an illumination adjustment apparatus. The illumination system can be configured to illuminate a pattern of a patterning device. The illumination adjustment apparatus can comprise a plate, actuators, and finger structures. The actuators can comprise coils disposed on the plate. The finger structures can comprise beryllium alloy material. Ones of the finger structures can be coupled to corresponding ones of the actuators via magnets. The finger structures can be configured to be moved independently using the actuators, to be disposed at least partially in a path of a beam of radiation to intercept at least a portion of the beam, and to adjust an intensity cross-section of the beam based on the moving and the intercepting.

In some aspects, an illumination adjustment apparatus can comprise a plate, actuators, and finger structures. The plate can comprise a fluid channel distributed throughout the plate. The fluid channel can be configured to circulate a cooling fluid throughout the plate and to introduce the cooling fluid at a center region of the plate before sending the cooling fluid to a peripheral region of the plate. The actuators can comprise coils disposed at the plate. At least a portion of the fluid channel can be disposed between at least two of the coils. Ones of the finger structures can be coupled to corresponding ones of the actuators via magnets. The finger structures can be configured to be moved independently using the actuators, to be disposed at least partially in a path of a beam of radiation to intercept at least a portion of the beam, and to adjust an intensity cross-section of the beam based on the moving and the intercepting.

In some aspects, a lithographic apparatus can comprise an illumination system and an illumination adjustment apparatus. The illumination system can be configured to illuminate a pattern of a patterning device. The illumination adjustment apparatus can comprise a plate, actuators, and finger structures. The plate can comprise a fluid channel distributed throughout the plate. The fluid channel can be configured to circulate a cooling fluid throughout the plate and to introduce the cooling fluid at a center region of the plate before sending the cooling fluid to a peripheral region of the plate. The actuators can comprise coils disposed at the plate. At least a portion of the fluid channel can be disposed between at least two of the coils. Ones of the finger structures can be coupled to corresponding ones of the actuators via magnets. The finger structures can be configured to be moved independently using the actuators, to be disposed at least partially in a path of a beam of radiation to intercept at least a portion of the beam, and to adjust an intensity cross-section of the beam based on the moving and the intercepting.

Further features of various aspects of the present disclosure are described in detail below with reference to the accompanying drawings. It is noted that the present disclosure is not limited to the specific aspects described herein. Such aspects are presented herein for illustrative purposes only. Additional aspects will be apparent to those skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable those skilled in the relevant art(s) to make and use aspects described herein.

FIG. 1A shows a reflective lithographic apparatus, according to some aspects.

FIG. 1B shows a transmissive lithographic apparatus, according to some aspects.

FIG. 2 shows more details of a reflective lithographic apparatus, according to some aspects.

FIG. 3 shows a lithographic cell, according to some aspects.

FIG. 4 shows a uniformity correction system, according to some aspects.

FIG. 5 shows finger structures that can be used in a uniformity correction system, according to some aspects.

FIG. 6 shows a plate that can be used in a uniformity correction system, according to some aspects.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

The aspects described herein, and references in the specification to “one aspect,” “an aspect,” “an exemplary aspect,” “an example aspect,” etc., indicate that the aspects described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of those skilled in the art to effect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The terms “about,” “approximately,” or the like can be used herein to indicate the value of a given quantity that can vary based on a particular technology. Based on the particular technology, the terms “about,” “approximately,” or the like can indicate a value of a given quantity that varies within, for example, 10-30% of the value (e.g., +10%, +20%, or +30% of the value).

Aspects of the present disclosure can be implemented in hardware, firmware, software, or any combination thereof. Aspects of the disclosure can also be implemented as instructions stored on a computer-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Furthermore, firmware, software, routines, and/or instructions can be described herein as performing certain actions. However, it should be appreciated that such descriptions are merely for convenience and that such actions result from computing devices, processors, controllers, or other devices executing the firmware, software, routines, instructions, etc. The term “machine-readable medium” can be interchangeable with similar terms, for example, “computer program product,” “computer-readable medium,” “non-transitory computer-readable medium,” or the like. The term “non-transitory” can be used herein to characterize one or more forms of computer readable media except for a transitory, propagating signal.

Before describing such aspects in more detail, however, it is instructive to present an example environment in which aspects of the present disclosure can be implemented.

### Example Lithographic Systems

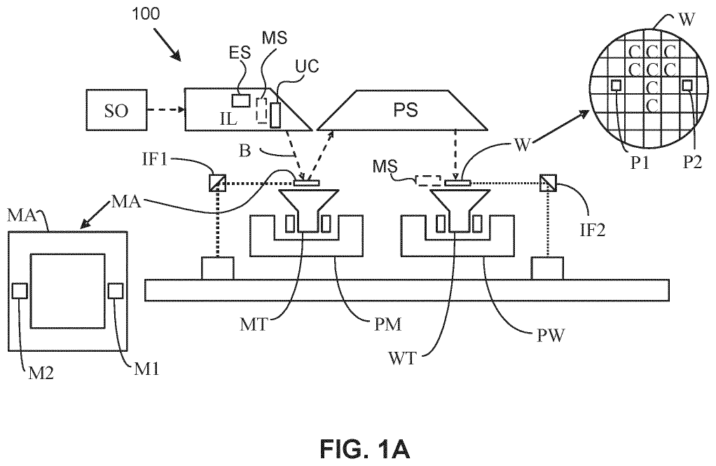

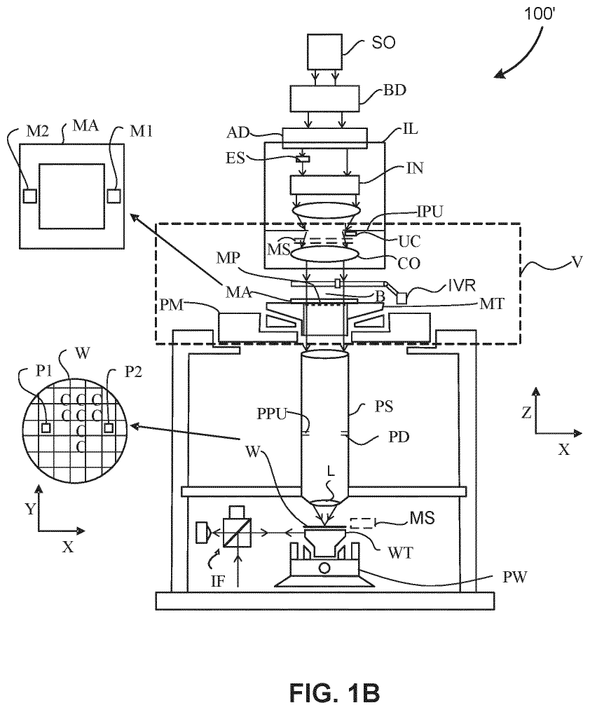

FIGS. 1A and 1B show a lithographic apparatus 100 and a lithographic apparatus 100′, respectively, in which aspects of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B. The illumination system IL can also include a sensor ES that provides a measurement of, for example, one or more of energy per pulse, photon energy, intensity, average power, and the like. The illumination system IL can include a measurement sensor MS for measuring a movement of the radiation beam B and uniformity compensators UC that allow an illumination slit uniformity to be controlled. The measurement sensor MS can also be disposed at other locations. For example, the measurement sensor MS can be on or near the substrate table WT.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA can be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid. For example, a liquid can be located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. A radiation system can comprise the source SO, the illuminator IL, and/or the beam delivery system BD.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross-section. The desired uniformity of radiation beam B can be maintained by using a uniformity compensator UC. Uniformity compensator UC comprises a plurality of protrusions (e.g., fingers) that can be adjusted in the path of radiation beam B to control the uniformity of radiation beam B. A sensor ES can be used to monitor the uniformity of radiation beam B.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU. A desired uniformity of radiation beam B can be maintained by using a uniformity compensator UC to control a uniformity of the radiation beam B. A sensor ES can be used to monitor the uniformity of radiation beam B.

The projection system PS projects an image of the mask pattern MP, where the image is formed by diffracted beams produced from the mark pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture (e.g., using a lens or lens group L) the zeroth order diffracted beams, first order diffracted beams, and/or higher order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some aspects, astigmatism aberration can be reduced by providing radiation poles (not shown) in opposite quadrants of the illumination system pupil IPU. Further, in some aspects, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of the vacuum chamber V. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots can be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-)magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as needed after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In a further aspect, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

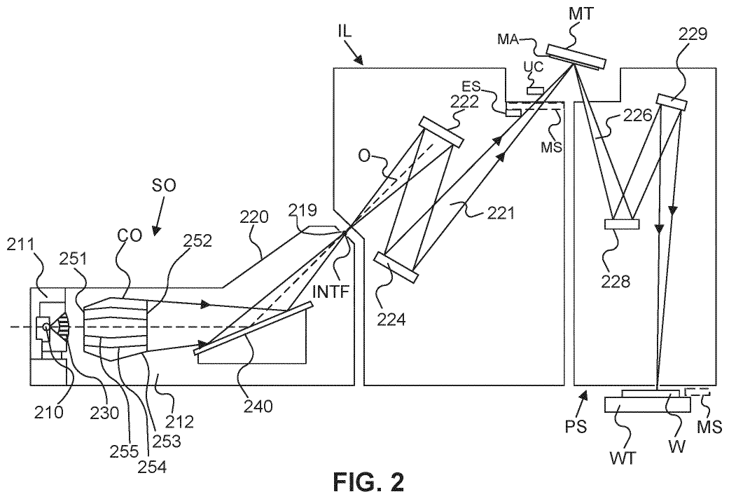

FIG. 2 shows the lithographic apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 can be formed by a discharge produced plasma source. EUV radiation can be produced by a gas or vapor, for example Xe gas, Li vapor, or Sn vapor in which EUV radiation emitting plasma 210 is created to emit radiation in the EUV range of the electromagnetic spectrum. The EUV radiation emitting plasma 210 is created by, for example, an electrical discharge causing at least a partially ionized plasma. Partial pressures of, for example, 10 Pa of Xe, Li, Sn vapor, or any other suitable gas or vapor can be used for efficient generation of the radiation. In some aspects, a plasma of excited tin (Sn) (e.g., excited via a laser) is provided to produce EUV radiation.

The radiation emitted by the EUV radiation emitting plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap or contaminant barrier 230 further indicated herein at least includes a channel structure.

The collector chamber 212 can include a radiation collector CO, which can be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the EUV radiation emitting plasma 210. Grating spectral filter 240 is used in particular for suppressing infra-red (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination optics unit IL and projection system PS. The grating spectral filter 240 can optionally be present, depending upon the type of lithographic apparatus. Further, there can be more mirrors present than those shown in the FIG. 2, for example there can be one to six additional reflective elements present in the projection system PS than shown in FIG. 2.

In some aspects, illumination optics unit IL can include a sensor ES that provides a measurement of, for example, one or more of energy per pulse, photon energy, intensity, average power, and the like. Illumination optics unit IL can include a measurement sensor MS for measuring a movement of the radiation beam B and uniformity compensators UC that allow an illumination slit uniformity to be controlled. The measurement sensor MS can also be disposed at other locations. For example, the measurement sensor MS can be on or near the substrate table WT.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Example Lithographic Cell

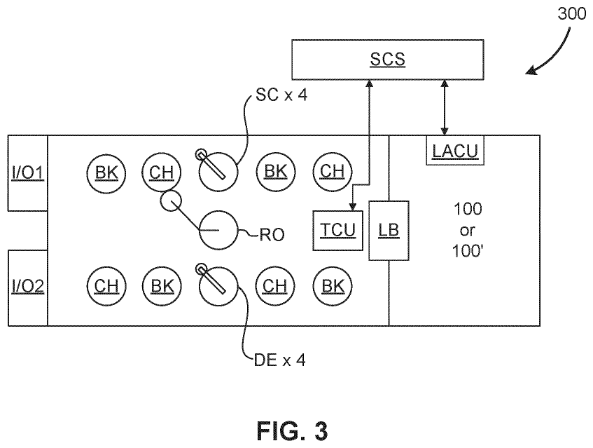

FIG. 3 shows a lithographic cell 300, also sometimes referred to a lithocell or cluster, according to some aspects. Lithographic apparatus 100 or 100′ can form part of lithographic cell 300. Lithographic cell 300 can also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Uniformity Correction System

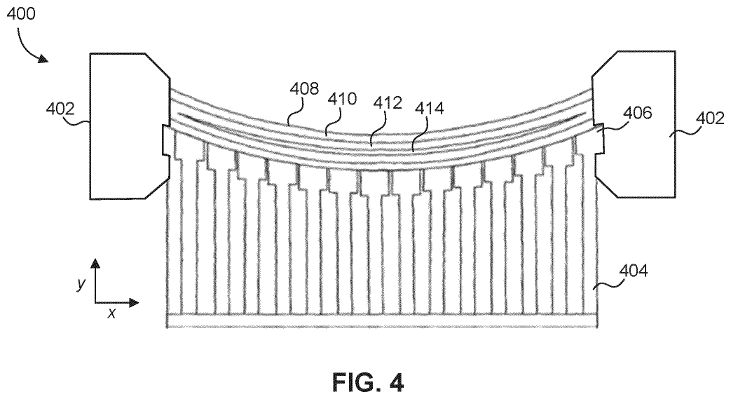

FIG. 4 shows a portion of a uniformity correction system 400, according to some aspects. In some aspects, uniformity correction system 400 can correspond to uniformity compensator UC in FIGS. 1A, 1B, and 2. Uniformity correction system 400 comprises a plurality of uniformity compensator elements 404 (e.g., fingers). Each of uniformity compensator elements 404 comprises a distal edge 406. Uniformity correction system 400 can work in connection with one or more sensors (e.g., ES and/or MS (FIGS. 1A, 1B, and 2)) to monitor and adjust an intensity profile of a beam of radiation.

A cross slot illumination 408 is shown in FIG. 4. Cross slot illumination 408 can also be referred to as a cross-section of a beam of radiation, a cross-section along a path of an beam of radiation, an illumination slit, or the like. Cross slot illumination 408 is represented as a 2D intensity map with different intensity regions 410, 412, and 414. For example, intensity region 410 has a low relative intensity and is disposed on the outer portion of cross slot illumination 408. Conversely, intensity region 414 has a high relative intensity and is disposed toward the center portion of cross slot illumination 408. In some aspects, a shape of the cross slot illumination 408 has a substantially arcuate geometry. Each distal edge 406 comprises a straight distal edge that is oriented to approximately follow a curvature of the arcuate geometry. In some aspects, a shape of the cross slot illumination 408 has a substantially rectangular geometry (not shown) and each distal edge comprises a straight edge that is oriented to approximately follow a shape of the rectangular geometry. Each of uniformity compensator elements 404 is attached to a corresponding actuator (not shown).

In some aspects, uniformity correction system 400 can modify or adjust an illumination beam used in a lithographic operation. For example, each of uniformity compensator elements 404 can be adjusted in the path of the illumination beam (e.g., at least overlapping cross slot illumination 408) using the corresponding actuators to conform an intensity profile of cross slot illumination 408 to a selected intensity profile. Hence, uniformity correction system 400 can also be referred to as an illumination adjustment apparatus. Example operations of uniformity compensators can be found in commonly owned U.S. Pat. No. 8,629,973 B2, filed May 28, 2010, and U.S. Pat. No. 9,134,620 B2, filed Apr. 12, 2012, which are incorporated by reference herein in their entirety.

In some aspects, a function of uniformity correction system 400 is to condition a beam of radiation such that the interaction between the beam of radiation and uniformity correction system 400 produce a resulting beam of radiation that has intensity characteristics that conform to a given specification. For example, it can be important for lithographic processes to use very specific doses of radiation so as to ensure pattern transfers from mask to wafer with as little error as possible. The cross-sectional intensity of a beam of radiation can fluctuate over time. The fluctuations can increase the likelihood of errors in pattern transfers. Uniformity correction system 400 can be used to control the cross-sectional intensity of a beam of radiation in order to reduce errors in pattern transfers.

The term “throughput” is commonly understood as the amount of material or items passing through a system or process. In some aspects, the term “throughput” can be used to characterize a rate of lithographic fabrication. For example, throughput can refer to a rate at which lithographic fabrication is completed on wafers, a rate at which a wafer clears a particular fabrication step and moves to the next step, or the like. Throughput can be a performance marker of a lithographic apparatus. It is desirable for lithographic systems to output as many products as possible in as little time as possible. Lithographic fabrication can comprise several complex processes. Each part of the process can involve tradeoffs that balance quality (e.g., sub-nanometer accuracy, high yield) and drawbacks (e.g., slower fabrication, cost). For example, to improve pattern-transfer accuracy, lithography can include fast actuation of compensator fingers to condition beams of radiation (to reduce pattern transfer errors).

However, in some aspects, mechanical systems like uniformity correction systems can have vibrational issues (e.g., resonant modes). Depending on the material and dimensions of the fingers, the vibrational issues can be more pronounced at higher actuation speeds. One can reduce the speed of actuation so as to reduce the effects of vibration modes, but at the cost of decreased throughput. Furthermore, high-speed actuation can generate high heat, increasing the likelihood of mechanical failure, reducing life expectancy of the affected components, and negatively impacting the overall performance of the uniformity correction system. Aspects described herein implement devices and functions to reduce vibrational and thermal effects in uniformity correction systems.

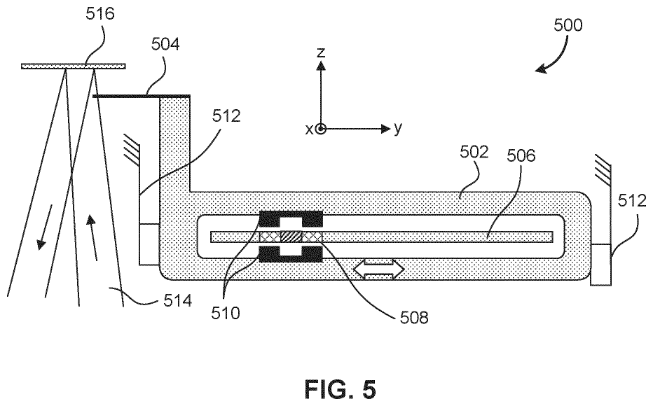

FIG. 5 shows a finger structure 500 that can be used in a uniformity correction system, according to some aspects. In some aspects, finger structure 500 can comprise a body 502 and a tip 504. An actuator portion of finger structure 500 can comprise a coil 508 and a magnet 510. Coil 508 can be disposed on a plate 506. Magnet 510 can be a magnet system (e.g., one or more magnets). Finger structure 500 can also comprise one or more flexures 512. The structures and functions of uniformity compensator elements 404 (FIG. 4) can be engineered according to finger structure 500 as described herein.

In some aspects, finger structure 500 can be positioned proximal to a path of a beam of radiation 514. A cross-section of beam of radiation 514 can correspond to cross slot illumination 408 (FIG. 4). Beam of radiation 514 can irradiate a patterning device 516. Patterning device 516 can impart a pattern on beam of radiation 514 so as to project an image of the pattern from the patterning device 516 and onto a substrate (pattern transfer). Patterning device 516 can be reflective or transmissive. It is important for the intensity profile of beam of radiation 514 to conform to tolerances of lithographic processes. One or more finger structures can be used to control the intensity profile of beam of radiation 514. For a grouping of finger structures, each finger structure 500 can be moved independently of the other finger structures. Finger structure 500 can be disposed at least partially in a path of beam of radiation 514 to intercept at least a portion of the beam. By moving finger structure 500 in and/or out of beam of radiation 514, the intensity cross-section of the beam can be adjusted.

In some aspects, the material of finger structure 500 can also have increased thermal stability and chemical stability. For example, the thermal conductivity of beryllium alloy can be higher than other candidate materials with stiffness and density similar to that of the beryllium alloy. Furthermore, beryllium alloy can be more corrosion-resistant in partial vacuum environments typically used in EUV lithography machines. For example, the material can be resistant to rarified hydrogen gas.

In some aspects, plate 506 can generate substantial heat due to the electrical power supplied to coil 508. Plate 506 can comprise a plurality of coils to drive a plurality of finger structures.

In some aspects, one or more flexures 512 can reduce vibrations of finger structure 500, particularly for movement along a length of finger structure 500 (e.g., along the y-axis as shown in FIG. 5). While one or more flexures 512 can provide some vibration control along a width of finger structure 500 (x-axis), it can be difficult to implement more rigorous vibration control in the limited space available when a plurality of finger structures are brought together side-by-side (e.g., as depicted in FIG. 4). The width dimension can be smaller than, and perpendicular to, the length. Vibrations along the x-axis can also be referred to as side-to-side vibrations, side vibrations, lateral vibrations, or the like. To circumvent this problem, finger structure 500 can comprise an ultra-light and ultra-stiff material, for example, a beryllium alloy. In a non-limiting example, body 502 can be made of a beryllium alloy. The lightness of the beryllium alloy promotes fast actuation of finger structure 500 while the increased stiffness can alter the bandwidth of vibrational modes such that vibrations are mitigated at the higher actuation speeds. The properties of the beryllium alloy can help increase the lower bound of the frequencies of the vibrational modes (that is, the frequencies at which the vibrations can absorb energy from the actuation). A minimum frequency for lateral vibrational modes can be pushed up to, for example, approximately 130 Hz or higher, 160 Hz or higher, 180 Hz or higher, 200 Hz or higher, or the like.

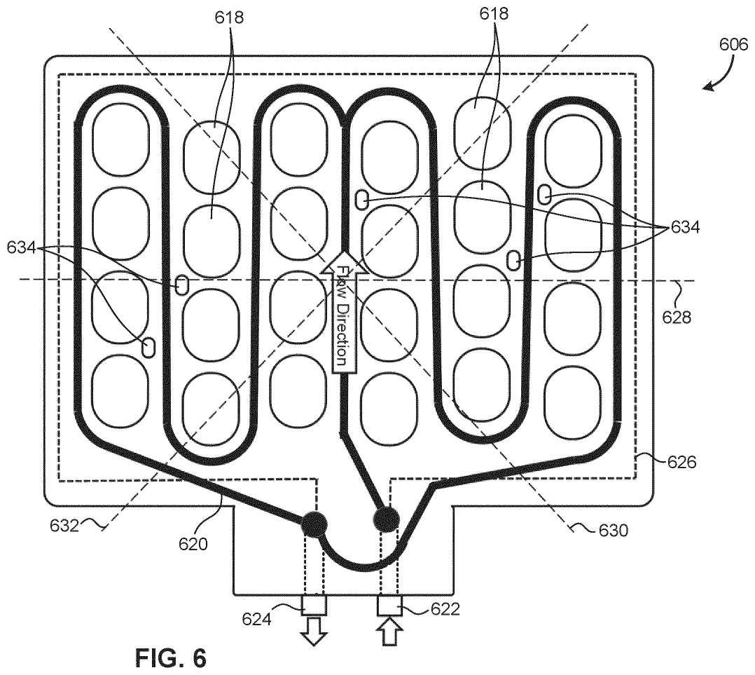

FIG. 6 shows a plate 606 that can be used in a uniformity correction system, according to some aspects. In some aspects, plate 606 can correspond to plate 506 in FIG. 5. Plate 606 can comprise a plurality of coil regions 618 and a fluid channel 620. An actuator coil (e.g., coil 508 (FIG. 5)) can be disposed at each of coil regions 618. Plate 606 can be assembled along with a plurality of finger structures (e.g., finger structure 500 (FIG. 5)) to form a uniformity correction system (e.g., uniformity correction system 400 (FIG. 4)). Fluid channel 620 can comprise an inlet 622 and an outlet 624.

In some aspects, as the uniformity correction system is used more intensely (e.g., more power to the coils for faster actuation), plate 606 can accumulate a considerable amount of heat, which can result in poor device performance or even irreversible damage. Therefore, fluid channel 620 can provide cooling fluid to cool plate 606 uniformity correction assembly. In one example, fluid channel 620 can route the cooling fluid around the periphery of plate 606 (illustrated as dashed line 626). While such a design can be desirable for its simplicity, a problem with the design is that the cooling fluid has limited ability to cool the center of plate 606. The resulting heat gradient could affect the actuation functions of the uniformity correction system and also the accuracy of the positioning of the finger structures. Therefore, fluid channel 620 can be structured so as to circulate a cooling fluid throughout plate 606. Furthermore, the cooling fluid can be introduced at a center region of plate 606 (e.g., via inlet 622) before sending the cooling fluid to a peripheral region of plate 606, or vice versa. Fluid channel 620 can also have a serpentine structure. Coil regions 618 can be disposed in rows. Fluid channel 620 can be present between all rows of coil regions 618 to optimize cooling. Fluid channel 620 can be disposed between two or more of the coils so that the cooling fluid can flow adjacent to every heat-producing coil, which may not be possible if fluid channel 620 were to be shaped like dashed line 626.

In some aspects, inlets and outlets of the cooling system can be engineered to accommodate spatial constraints. A space-saving design can include having inlet 622 and outlet 624 on a same side of plate 606 so as to be able to arrange the supply and return lines of the cooling fluid side-by-side. In this context, a side need not strictly refer to an edge or periphery. For example, a line 628 can approximately bisect plate 606 as shown in FIG. 6, which can define a top side (above line 628) and a bottom side (below line 628). Then, according to this non-limiting example, inlet 622 and outlet 624 can both be disposed on the bottom side (that is, on a side that is below line 628).

In some aspects, plate 606 can be arranged into quadrants (e.g., as defined by example lines 630 and 632). Then, according to this non-limiting example, inlet 622 and outlet 624 can both be disposed on the same quadrant.

In some aspects, when spatial constraints are less strict, inlet 622 and outlet 624 can be disposed on different sides or different quadrants.

In some aspects, plate 606 can have a thickness along a height direction. The height direction in FIG. 6, thickness can be defined into or out of the page. Fluid channel 620 can be disposed at a first height or plane. Alternatively, the distribution and disposition of fluid channel 620 can define a first plane. Inlet 622 and/or outlet 624 can be disposed on a second plane that is offset from the first plane. This arrangement can be particularly useful for accommodating inlet 622 and outlet 624 to be on the same side or quadrant. As shown in FIG. 6, inlet 622 can be routed over a section of fluid channel 620 so as to not conflict with the intended flow path of the cooling fluid. In some aspects, it is desirable to reduce volume and footprint of the uniformity correction system (e.g., design with a small thickness, design a gap between magnet and plate 506 and magnets 510 as small as possible (FIG. 5)). In some aspects, a cooling scheme can route the flow out of plane from the coils. But this can significantly increase the gap and/or decrease overall performance. Therefore, in some aspects, the flow can be in line with the coils instead of out of plane.

In some aspects, plate 606 can comprise a plurality of sensor regions 634. Thermal sensors (e.g., thermistors) can be disposed at sensor regions 634. As shown by the distribution of sensor regions 634 in FIG. 6, the thermal sensor can cover a wide area of plate 606 so as to allow monitoring of temperatures of the cooling fluid as the cooling fluid progresses from a center region of plate 606 to a peripheral region of plate 606. The sensing of the temperature gradient throughout plate 606 can provide indication of a working condition of the uniformity correction system (e.g., in working order, faulty coil, cooling failure, or the like). In some aspects, sensors can be provided as close pairs to provide redundancy. Each of a pair of sensors can be disposed on either side of a segment of fluid channel 620. By gathering information from a pair of channels, it is envisaged that an error can be detected in the event that one sensor fails.

The terms “radiation,” “beam,” “light,” “illumination,” or the like can be used herein to refer to one or more types of electromagnetic radiation, for example, ultraviolet (UV) radiation (for example, having a wavelength 2 of 365, 248, 193, 157 or 126 nm), extreme ultraviolet (EUV or soft X-ray) radiation (for example, having a wavelength in the range of 5-100 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some aspects, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

The embodiments may further be described using the following clauses:
1. An illumination adjustment apparatus comprising:
a plate;
actuators comprising coils;
finger structures comprising beryllium alloy material, wherein ones of the finger structures are coupled to corresponding ones of the actuators via magnets, and wherein the finger structures are configured to: be moved independently using the actuators;
be disposed at least partially in a path of a beam of radiation to intercept at least a portion of the beam; and
adjust an intensity cross-section of the beam.
2. The illumination adjustment apparatus of clause 1, further comprising flexures attached to the finger structures, wherein the flexures are configured to reduce vibrations of the finger structures.
3. The illumination adjustment apparatus of clause 1, wherein:
the finger structures have a width and a length;
the width is shorter than, and perpendicular to, the length;
the finger structures have lateral vibrational modes along the width; and
a minimum frequency for the lateral vibrational modes is approximately 130 Hz or higher.
4. The illumination adjustment apparatus of clause 1, wherein:
the plate comprises a fluid channel distributed throughout the plate; and
the fluid channel is configured to circulate a cooling fluid throughout the plate and to introduce the cooling fluid at a center region of the plate before sending the cooling fluid to a peripheral region of the plate.
5. A lithographic apparatus comprising:
an illumination system configured to illuminate a pattern of a patterning device; and
an illumination adjustment apparatus comprising:
a plate;
actuators comprising coils;
finger structures comprising beryllium alloy material, wherein ones of the finger structures are coupled to corresponding ones of the actuators via magnets, and wherein the finger structures are configured to:
be moved independently using the actuators;
be disposed at least partially in a path of a beam of radiation to intercept at least a portion of the beam; and
adjust an intensity cross-section of the beam.
6. The lithographic apparatus of clause 5, wherein:
the illumination adjustment apparatus further comprises flexures attached to the finger structures, and
the flexures are configured to reduce vibrations of the finger structures.
7. The lithographic apparatus of clause 5, wherein:
the finger structures have a width and a length;
the width is shorter than, and perpendicular to, the length;
the finger structures have lateral vibrational modes along the width; and
a minimum frequency for the lateral vibrational modes is approximately 130 Hz or higher.
8. The lithographic apparatus of clause 5, wherein:
the plate comprises a fluid channel distributed throughout the plate; and
the fluid channel is configured to circulate a cooling fluid throughout the plate and to introduce the cooling fluid at a center region of the plate before sending the cooling fluid to a peripheral region of the plate.
9. An illumination adjustment apparatus comprising:
a plate comprising a fluid channel distributed throughout the plate, wherein the fluid channel is configured to circulate a cooling fluid throughout the plate and to introduce the cooling fluid at a center region of the plate before sending the cooling fluid to a peripheral region of the plate;
actuators comprising coils, wherein at least a portion of the fluid channel is disposed between at least two of the coils;
finger structures, wherein ones of the finger structures are coupled to corresponding ones of the actuators via magnets, and wherein the finger structures are configured to:
be moved independently using the actuators;
be disposed at least partially in a path of a beam of radiation to intercept at least a portion of the beam; and
adjust an intensity cross-section of the beam.
10. The illumination adjustment apparatus of clause 9, wherein:
the fluid channel comprises an inlet and an outlet; and
the inlet and the outlet are disposed on a same side of the plate.
11. The illumination adjustment apparatus of clause 9, wherein:
the fluid channel comprises an inlet and an outlet; and
the inlet and the outlet are disposed on different sides of the plate.
12. The illumination adjustment apparatus of clause 9, wherein:
the fluid channel comprises an inlet and an outlet; and
the inlet and the outlet are disposed on a same quadrant of the plate.
13. The illumination adjustment apparatus of clause 9, wherein:
the fluid channel comprises an inlet and an outlet; and
the inlet and the outlet are disposed on different quadrants of the plate.
14. The illumination adjustment apparatus of clause 9, wherein:
the fluid channel defines a plane; and
the inlet and/or outlet can be disposed offset from the plane.
15. The illumination adjustment apparatus of clause 9, further comprising thermal sensors.
16. The illumination adjustment apparatus of clause 15, wherein at least one of the thermal sensors is disposed proximal to the center region and another one of the thermal sensors is disposed proximal to the peripheral region.
17. The illumination adjustment apparatus of clause 9, wherein at least a portion of the fluid channel can be structured according to a serpentine structure.
18. The illumination adjustment apparatus of clause 9, wherein fluid channel is structured such that every one of the coils is adjacent to a portion of the fluid channel.
19. The illumination adjustment apparatus of clause 9, wherein the finger structures comprise beryllium alloy material.
20. A lithographic apparatus comprising:
an illumination system configured to illuminate a pattern of a patterning device; and
an illumination adjustment apparatus comprising:
a plate comprising a fluid channel distributed throughout the plate, wherein the fluid channel is configured to circulate a cooling fluid throughout the plate and to introduce the cooling fluid at a center region of the plate before sending the cooling fluid to a peripheral region of the plate; actuators comprising coils, wherein at least a portion of the fluid channel is disposed between at least two of the coils;
finger structures, wherein ones of the finger structures are coupled to corresponding ones of the actuators via magnets, and wherein the finger structures are configured to:
be moved independently using the actuators;
be disposed at least partially in a path of a beam of radiation to intercept at least a portion of the beam;
and adjust an intensity cross-section of the beam.

Although some aspects of the present disclosure are described in the context of lithographic apparatuses in the manufacture of ICs, it should be understood that lithographic apparatuses described herein can be used in other applications, for example, in the manufacture of integrated optical systems, guidance and detection patterns for magnetic domain memories, flat-panel displays, LCDs, thin-film magnetic heads, etc. Those skilled in the art will appreciate that, in the context of such alternative applications, any use of the terms “wafer” or “die” herein can be considered as specific examples of the more general terms “substrate” or “target portion”, respectively. A substrate can be processed before or after exposure in, for example, a track unit (a tool that typically applies a layer of resist to a substrate and develops the exposed resist) and/or a metrology unit. Where applicable, aspects disclosed herein can be applied to such and other substrate processing tools. Furthermore, a substrate can be processed more than once, for example in order to create a multi-layer IC, so that the term substrate used herein can also refer to a substrate that already contains multiple processed layers.

Furthermore, although some aspects of the present disclosure are described in the context of optical lithography, it should be understood that aspects of the present disclosure are not limited to optical lithography. For example, in imprint lithography, a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed. The foregoing description of specific aspects will so fully reveal the general nature of the present disclosure that others can, by applying knowledge within the skill of the art, readily modify and/or adapt for various applications such specific aspects, without undue experimentation and without departing from the general concept of the present disclosure. Therefore, such adaptations and modifications are intended to be within the meaning and range of equivalents of the disclosed aspects, based on the teaching and guidance presented herein.

It is to be understood that the Detailed Description section, and not the Summary and Abstract sections, is intended to be used to interpret the claims. The Summary and Abstract sections can set forth one or more, but not necessarily all, aspects of the present disclosure as contemplated by the inventor(s), and thus, are not intended to limit the present disclosure and the appended claims in any way. The breadth and scope of the protected subject matter should not be limited by any of the above-described aspects, but should be defined in accordance with the following claims and their equivalents.

1.-15. (canceled)

16. An illumination adjustment apparatus comprising:
a plate;
actuators comprising coils disposed on the plate;
finger structures comprising beryllium alloy material, wherein ones of the finger structures are coupled to corresponding ones of the actuators via magnets, and wherein the finger structures are configured to:
be moved independently using the actuators;
be disposed at least partially in a path of a beam of radiation to intercept at least a portion of the beam; and
adjust an intensity cross-section of the beam.

17. The illumination adjustment apparatus of claim 1, further comprising flexures attached to the finger structures, wherein the flexures are configured to reduce vibrations of the finger structures.

18. The illumination adjustment apparatus of claim 16, wherein:
the finger structures have a width and a length;
the width is shorter than, and perpendicular to, the length;
the finger structures have lateral vibrational modes along the width; and
a minimum frequency for the lateral vibrational modes is approximately 130 Hz or higher.

19. The illumination adjustment apparatus of claim 16, wherein:
the plate comprises a fluid channel distributed throughout the plate; and
the fluid channel is configured to circulate a cooling fluid throughout the plate and to introduce the cooling fluid at a center region of the plate before sending the cooling fluid to a peripheral region of the plate.

20. A lithographic apparatus comprising:
an illumination system configured to illuminate a pattern of a patterning device; and
an illumination adjustment apparatus comprising:
a plate;
actuators comprising coils disposed on the plate;
finger structures comprising beryllium alloy material, wherein ones of the finger structures are coupled to corresponding ones of the actuators via magnets, and wherein the finger structures are configured to:
be moved independently using the actuators;
be disposed at least partially in a path of a beam of radiation to intercept at least a portion of the beam; and
adjust an intensity cross-section of the beam.

21. The lithographic apparatus of claim 20, wherein:
the illumination adjustment apparatus further comprises flexures attached to the finger structures, and
the flexures are configured to reduce vibrations of the finger structures.

22. The lithographic apparatus of claim 20, wherein:
the finger structures have a width and a length;
the width is shorter than, and perpendicular to, the length;
the finger structures have lateral vibrational modes along the width; and
a minimum frequency for the lateral vibrational modes is approximately 130 Hz or higher.

23. The lithographic apparatus of claim 20, wherein:
the plate comprises a fluid channel distributed throughout the plate; and
the fluid channel is configured to circulate a cooling fluid throughout the plate and to introduce the cooling fluid at a center region of the plate before sending the cooling fluid to a peripheral region of the plate.

24. An illumination adjustment apparatus comprising:
a plate comprising a fluid channel distributed throughout the plate, wherein the fluid channel is configured to circulate a cooling fluid throughout the plate and to introduce the cooling fluid at a center region of the plate before sending the cooling fluid to a peripheral region of the plate;
actuators comprising coils disposed on the plate, wherein at least a portion of the fluid channel is disposed between at least two of the coils;
finger structures, wherein ones of the finger structures are coupled to corresponding ones of the actuators via magnets, and wherein the finger structures are configured to:
be moved independently using the actuators;
be disposed at least partially in a path of a beam of radiation to intercept at least a portion of the beam; and
adjust an intensity cross-section of the beam.

25. The illumination adjustment apparatus of claim 24, wherein:
the fluid channel comprises an inlet and an outlet; and
the inlet and the outlet are disposed on a same side of the plate.

26. The illumination adjustment apparatus of claim 24, wherein:
the fluid channel comprises an inlet and an outlet; and
the inlet and the outlet are disposed on different sides of the plate.

27. The illumination adjustment apparatus of claim 24, wherein:
the fluid channel comprises an inlet and an outlet; and
the inlet and the outlet are disposed on a same quadrant of the plate.

28. The illumination adjustment apparatus of claim 24, wherein:
the fluid channel comprises an inlet and an outlet; and
the inlet and the outlet are disposed on different quadrants of the plate.

29. The illumination adjustment apparatus of claim 24, wherein:
the fluid channel defines a plane; and
the inlet and/or outlet can be disposed offset from the plane.

30. The illumination adjustment apparatus of claim 24, further comprising thermal sensors.

31. The illumination adjustment apparatus of clause 15, wherein at least one of the thermal sensors is disposed proximal to the center region and another one of the thermal sensors is disposed proximal to the peripheral region.

32. The illumination adjustment apparatus of claim 24, wherein at least a portion of the fluid channel can be structured according to a serpentine structure.

33. The illumination adjustment apparatus of claim 24, wherein fluid channel is structured such that every one of the coils is adjacent to a portion of the fluid channel.

34. The illumination adjustment apparatus of claim 24, wherein the finger structures comprise beryllium alloy material.
